(19) United States
(12) Patent Application Publication
(10) Pub. No.: US 2009/0226677 A1
(43) Pub. Date: Sep. 10, 2009

(54) LITHOGRAPHIC APPARATUS AND METHOD

(75) Inventor: Vincent PICI, Fremont, CA (US)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 12/392,882

(22) Filed: Feb. 25, 2009

Related U.S. Application Data
(60) Provisional application No. 61/064,409, filed on Mar. 4, 2008.

(51) Int. Cl. B32B 3/10; G03B 27/42; G03F 7/20

(52) U.S. Cl. 428/195.1; 355/53; 430/322

(57) ABSTRACT

According to an aspect of the invention, there is provided a lithographic apparatus including an illumination system for providing a beam of radiation, a support structure for supporting a patterning device, the patterning device serving to impart the radiation beam with a pattern in its cross-section; a substrate table for holding a substrate, and a projection system for projecting the patterned radiation beam onto a target portion of the substrate, wherein a pattern which the patterning device provides is rotatable, and the substrate is rotatable, rotation of the pattern being arranged to be proportional to rotation of the substrate, such that, after rotation, a pattern applied to the substrate is arranged to have the same orientation with respect to the substrate as it would if the pattern and substrate had not been rotated.

### CROSS-REFERENCE TO RELATED APPLICATION

This application claims priority and benefit under 35 U.S.C. § 119(e) to U.S. Provisional Patent Application No. 61/064,409, entitled “Lithographic Apparatus and Method”, filed on Mar. 4, 2008. The content of that application is incorporated herein in its entirety by reference.

### FIELD

The present invention relates to a lithographic apparatus and method.

### BACKGROUND

A lithographic apparatus is a machine that applies a desired pattern onto a target portion of a substrate. Lithographic apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g., comprising part of, one or several dies) on a substrate (e.g., a silicon wafer) that has a layer of radiation-sensitive material (resist). In general, a single substrate will contain a network of adjacent target portions that are successively exposed. Known lithographic apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti-parallel to this direction.

In order to create a device or the like using a lithographic apparatus, it is often necessary to apply to the substrate a plurality of different patterns. The plurality of different patterns may be overlaid on top of one another. Alternatively, the plurality of patterns may be applied to opposite sides of the substrate. In either case, the patterns have to be accurately aligned with one another in order to ensure that the resultant device works as intended. Any deviation in the shape or position of an applied pattern from an intended shape or position can result in successively applied patterns not being aligned with one another, which can result in what is known in the art as an overlay error. The greater the overlay error, the greater the chances that the resultant device will not work satisfactorily, or at all.

It is desirable to provide, for example, a lithographic apparatus and method that obviates or mitigates one or more of the problems of the prior art, whether identified herein or elsewhere.

### SUMMARY

According to a first aspect of the invention, there is provided a lithographic apparatus comprising: an illumination system for providing a beam of radiation; a support structure for supporting a patterning device, the patterning device serving to impart the radiation beam with a pattern in its cross-section; a substrate table for holding a substrate; and

a projection system for projecting the patterned radiation beam onto a target portion of the substrate; wherein a pattern which the patterning device provides is rotatable; and the substrate is rotatable, rotation of the pattern being arranged to be proportional to rotation of the substrate, such that, after rotation, a pattern applied to the substrate is arranged to have the same orientation with respect to the substrate as it would if the pattern and substrate had not been rotated.

According to a second aspect of the invention, there is provided a method comprising: providing a substrate; providing a beam of radiation using an illumination system; using a patterning device to impart the radiation beam with a pattern in its cross-section; and projecting the patterned radiation beam onto a target portion of the substrate; wherein the method further comprises: rotating the substrate; and rotating a pattern provided by the patterning device, rotation of the pattern being arranged to be proportional to rotation of the substrate, such that, after rotation, a pattern applied to the substrate is arranged to have the same orientation with respect to the substrate as it would if the pattern and substrate had not been rotated.

According to a third aspect of the invention, there is provided a device manufactured according to the method or apparatus of the first and second aspects of the invention.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically depicts a lithographic apparatus according to an embodiment of the invention;

FIGS. 2a to 2f schematically depict the application of patterns to opposite sides of a substrate;

FIGS. 3a and 3b schematically depict ideal and real properties of a pattern applied to a substrate;

FIG. 4 schematically depicts overlaid patterns using a first process;

FIG. 5 schematically depicts overlaid patterns using a second process;

FIG. 6 schematically depicts relative rotation of a fingerprint of the lithographic apparatus shown in FIG. 1 in accordance with an embodiment of the present invention;

FIG. 7 schematically depicts how the rotation of the fingerprint of the lithographic apparatus affects the overlaying of patterns as shown in FIG. 5;

FIG. 8 schematically depicts how relative rotation of the fingerprint of the lithographic apparatus may be undertaken in accordance with an embodiment of the present invention; and

FIGS. 9a to 9e schematically depict synchronous rotation of a patterning device and substrate in accordance with an embodiment of the present invention.

### DETAILED DESCRIPTION

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g., having a wavelength of 365, 248, 193, 157 or 126 nm) and extreme ultra-violet (EUV) radiation (e.g., having a wavelength in the range of 5-20 nm), as well as particle beams, such as ion beams or electron beams.

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

The support structure holds the patterning device. It holds the patterning device in a way depending on the orientation of the patterning device, the design of the lithographic apparatus, and other conditions, such as for example whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “projection lens” herein may be considered as synonymous with the more general term “projection system”.

The illumination system may also encompass various types of optical components, including refractive, reflective, and catadioptric optical components for directing, shaping, or controlling the beam of radiation, and such components may also be referred to below, collectively or singularly, as a “lens”.

The lithographic apparatus may be of a type having two (dual stage) or more substrate tables (and/or two or more support structures). In such “multiple stage” machines the additional tables may be used in parallel, or preparatory steps may be carried out on one or more tables while one or more other tables are being used for exposure.

The lithographic apparatus may also be of a type wherein the substrate is immersed in a liquid having a relatively high refractive index, e.g., water, so as to fill a space between the final element of the projection system and the substrate. Immersion techniques are well known in the art for increasing the numerical aperture of projection systems.

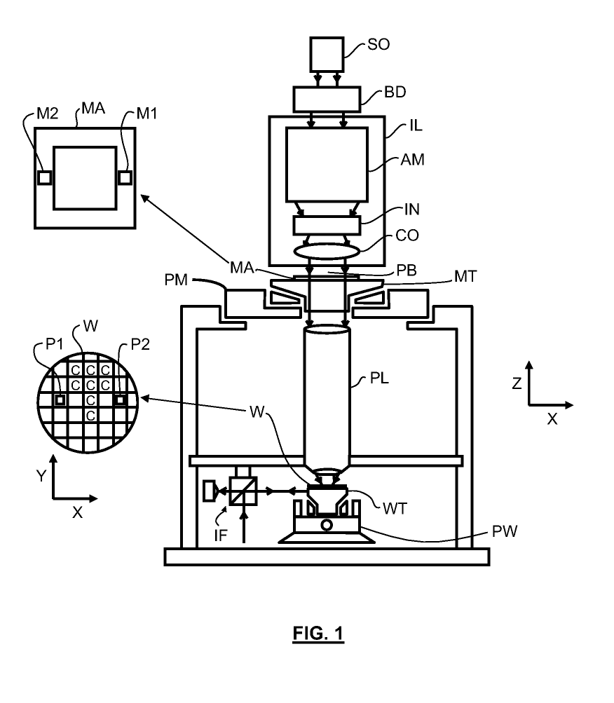

FIG. 1 schematically depicts a lithographic apparatus according to a particular embodiment of the invention. The apparatus comprises:
an illumination system (illuminator) IL to condition a beam PB of radiation (e.g., UV, DUV or EUV radiation).
a support structure (e.g., a support structure) MT to support a patterning device (e.g., a mask) MA and connected to first positioning device PM to accurately position the patterning device with respect to item PL;
a substrate table (e.g., a wafer table) WT for holding a substrate (e.g., a resist-coated wafer) W and connected to second positioning device PW for accurately positioning the substrate with respect to item PL; and
a projection system (e.g., a refractive projection lens) PL configured to image a pattern imparted to the radiation beam PB by patterning device MA onto a target portion C (e.g., comprising one or more dies) of the substrate W.

As here depicted, the apparatus is of a transmissive type (e.g., employing a transmissive mask). Alternatively, the apparatus may be of a reflective type (e.g., employing a programmable mirror array of a type as referred to above).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases the source may be integral part of the apparatus, for example when the source is a mercury lamp. The source SO and the illuminator IL, together with the beam delivery system BD if required, may be referred to as a radiation system.

The illuminator IL may comprise adjustable optical elements AM for adjusting the angular intensity distribution of the beam. Generally, at least the outer and/or inner radial extent (commonly referred to as c-outer and w-inner, respectively) of the intensity distribution in a pupil plane of the illuminator can be adjusted. In addition, the illuminator IL generally comprises various other components, such as an integrator IN and a condenser CO. The illuminator provides a conditioned beam of radiation PB, having a desired uniformity and intensity distribution in its cross-section.

The radiation beam PB is incident on the patterning device (e.g., mask) MA, which is held on the support structure MT. Having traversed the patterning device MA, the beam PB passes through the lens PL, which focuses the beam onto a target portion C of the substrate W. With the aid of the second positioning device PW and position sensor IF (e.g., an interferometric device), the substrate table WT can be moved accurately, e.g., so as to position different target portions C in the path of the beam PB. Similarly, the first positioning device PM and another position sensor (which is not explicitly depicted in FIG. 1) can be used to accurately position the patterning device MA with respect to the path of the beam PB, e.g., after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner) the support structure MT may be connected to a short stroke actuator only, or may be fixed. Patterning device MA and substrate W may be aligned using patterning device alignment marks M1, M2 and substrate alignment marks P1, P2.

The depicted apparatus can be used in the following preferred modes:

1. In step mode, the support structure MT and the substrate table WT are kept essentially stationary, while an entire pattern imparted to the beam PB is projected onto a target portion C in one go (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the beam PB is projected onto a target portion C (i.e., a single dynamic exposure). The velocity and direction of the substrate table WT relative to the support structure MT is determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the beam PB is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

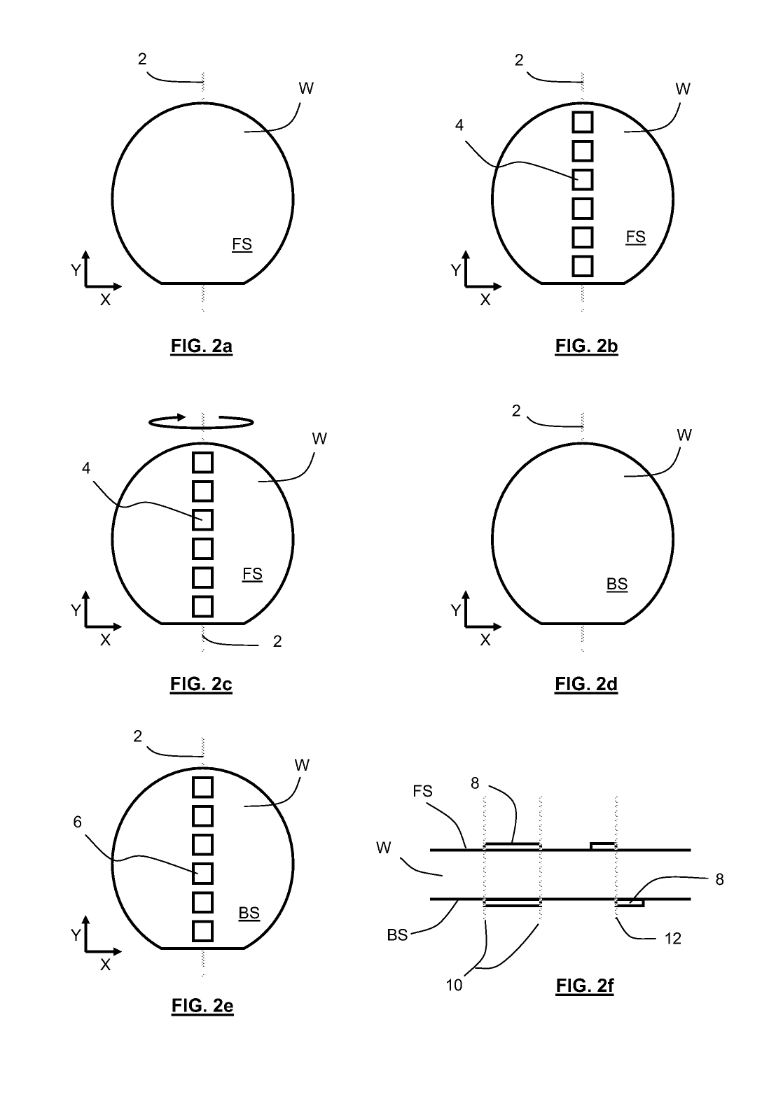

FIGS. 2a to 2f schematically depict a process that may be undertaken on the substrate W of FIG. 1. FIG. 2a shows the substrate W in plan view. The substrate W has two sides on which patterns may be applied. These sides are known in the art as a front-side and a back-side of the substrate W, the front-side being on an opposite side of the substrate W to the back-side. FIG. 2a shows the front-side FS of the substrate W. A centreline 2 of the substrate W in the y-direction is also shown.

FIG. 2b shows that a plurality of patterns 4 have been applied to the front-side of the substrate W using, for example, the lithographic processes described above. FIG. 2c shows how the substrate W is flipped about the centreline 2. Flipping of the substrate may be undertaken using a robotic arm, or the like. The substrate W is flipped so that patterns may be applied to the back-side of the substrate W. FIG. 2d shows the back-side BS of the substrate W. FIG. 2e shows that a plurality of further patterns 6 are applied to the back-side BS of the substrate W using, for example, the lithographic processes described above.

FIG. 2f shows the substrate W in side view. Pattern features 8 are shown on the front-side FS and back-side BS of the substrate W. As mentioned above, in order to ensure that a device comprising one or more of the pattern features 8 works reliably, or at all, it is desirable to ensure that the pattern features 8 are positioned accurately with respect to one another, or in other words that successively applied patterns to the front-side FS or back-side BS (or both sides) on the substrate W are accurately overlaid. In some circumstances, this may mean that the pattern features 8 are, as far as possible, in exact alignment with one another 10, or that pattern features 8 are aligned as closely as possible to one another without any overlap 12.

If the patterns or pattern features are not accurately overlaid, overlay errors are therefore present. Overlay errors can arise for one of a number of reasons. For instance, overlay errors can arise from inaccurate positioning of apparatus which holds or moves the substrate, or distortion of one or more elements of the lithographic apparatus, such as the patterning device or projection system. However, overlay errors can also occur for other reasons.

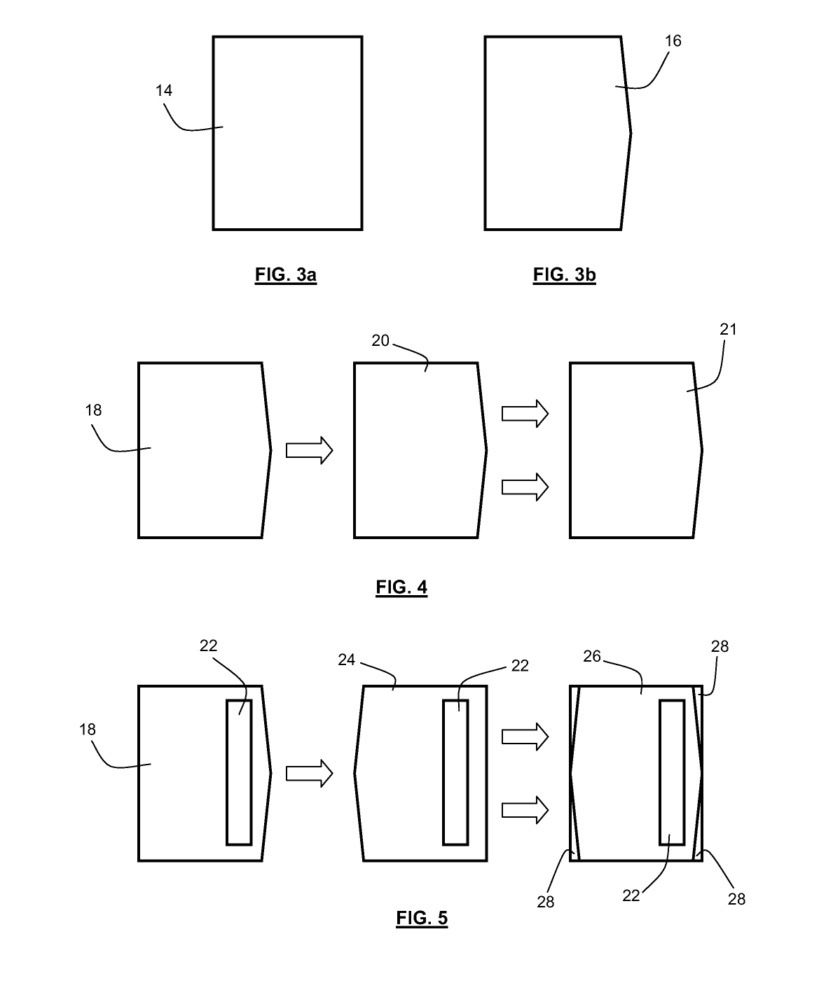

A lithographic apparatus will have an associated “fingerprint” associated with it. This fingerprint may arise from slight defectivities, imperfections, anomalies, etc. in elements of the lithographic apparatus, for example elements of the illumination system or projection system. This fingerprint will be imparted into the radiation beam, and will therefore have an affect on patterns applied to the substrate. For instance, FIG. 3a depicts a theoretical component part of a pattern 14 to be applied to a substrate. It can be seen that the component part 14 is rectangular in shape. FIG. 3b, on the other hand, shows the component-part in practice 16 (i.e., a ‘real’ component part). It can be seen that the component part 16 is substantially rectangular but is slightly distorted on its right-hand side as shown in the Figure. This distortion is a result of the fingerprint of the lithographic apparatus, for example arising from a distortion in the radiation beam caused by a non-uniformity or defect in the projection system or illumination system. It will be appreciated that the distortion of the component part of the pattern 16 is exaggerated for explanatory purposes only. The exact shape, type and extent of the distortion may not be as depicted in the Figure.

FIG. 4 schematically depicts a first component part of a pattern 18 that has been distorted due to the fingerprint of the lithographic apparatus. The Figure depicts the first distorted component part 18 being overlaid onto a second distorted component part 20 already applied to the substrate. The resultant overlaid distorted patterns 21 are shown. It can be seen that, because the fingerprint and therefore distortion is the same for the first and second distorted component parts 18, 20, there is little or no overlay error between the resultant overlaid patterns 21.

As mentioned above, in order to apply patterns to both sides of a substrate, it is sometimes necessary to flip the substrate over so that patterns can be applied to the front-side of the substrate, as well as the back-side of the substrate. If, for example, the substrate is flipped about an axis extending in the y direction as shown in FIG. 2c, it may be necessary to also flip (or in other words mirror) the pattern applied to the back-side of the substrate to take into account the flipping of the substrate. The pattern may be flipped by appropriate control of the patterning device or other parts of the lithographic apparatus. Even if the pattern is flipped, however, the fingerprint of the lithographic apparatus, and its corresponding effect on the pattern, is not flipped.

FIG. 5 shows the first distorted component part of a pattern 18. A pattern feature 22 is also shown. The Figure also shows a second distorted component part 24 as it would appear when it is flipped and applied to another side of a flipped substrate. The resultant pattern 24 and pattern feature 22 are shown. It can be seen that because of the flipping of the pattern and the substrate, the pattern feature 22 appears in the same location as it does in the un-flipped component part 18. However, as mentioned above, the fingerprint of the lithographic apparatus is not flipped by flipping the component part 18. Therefore, flipping the substrate and applying the flipped pattern to the substrate means that the distortion of the component part caused by the fingerprint of the lithographic apparatus will be in an opposite sense to a component on another opposite side of the substrate (i.e., because the substrate is flipped, but the fingerprint is not). The outline of the resultant overlaid patterns 26 (i.e., projected onto each other through the substrate) is shown. Even though the pattern feature 22 is well aligned in both component parts 18, 24, due to the distortion of the component parts 18, 24 being in an opposite sense, overlay errors 28 have arisen, where the distortion of one component part 18 on one side of the substrate results in areas of that component part 18 not being in alignment with areas of the component part 24 applied on another, opposite side of the substrate.

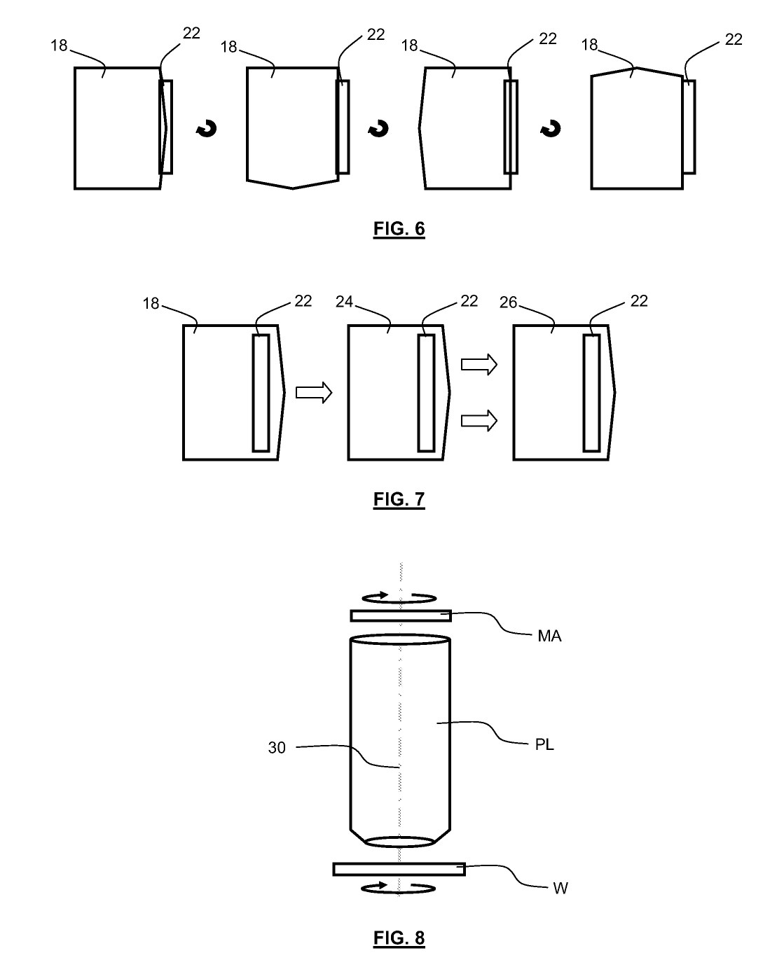

It has been found that this problem can be overcome by relative rotation or flipping (etc) of the fingerprint of the lithographic apparatus. FIG. 6 shows the first distorted component part 18 and the pattern feature 22 which it contains. Rotation of the fingerprint of the lithographic apparatus is schematically depicted in the Figure. It can be seen that although the fingerprint (and therefore the distortion of the pattern 18) is rotated, the pattern itself is not, as represented by the consistent location of the pattern feature 22 in the pattern 18 as the fingerprint is rotated.

FIG. 7 shows an application in which the fingerprint of the lithographic apparatus is rotated. Using the same process as depicted in FIG. 5, but rotating the fingerprint of the lithographic apparatus in-between the application of the first and second component parts 18, 24 to the substrate, it can be seen in FIG. 7 that the distortion of the overlaid component parts 26 is in the same sense (i.e., has the same orientation), thereby reducing or eliminating the overlay error that was present in the resultant pattern 26 shown in FIG. 5.

The fingerprint of the lithographic apparatus can be rotated in one of a number of ways. One way of rotating the fingerprint of the lithographic apparatus would be to keep the patterning device and the substrate stationary while rotating the element or elements of the lithographic apparatus which introduce the fingerprint. For example, the illumination system and projection system could be rotated. However, this is not practical due to the large size, cumbersome nature and sensitivity and tolerances of the illumination system and projection system. FIG. 8 schematically depicts a more practical approach for rotating the fingerprint of the lithographic apparatus. FIG. 8 shows some of the elements of the lithographic apparatus 1 shown in FIG. 1. Specifically, FIG. 8 shows the patterning device MA, the projection system PL and the substrate W. It can be seen that in order to rotate the fingerprint of the lithographic apparatus, the projection system PL is kept stationary, while the patterning device MA and the substrate W are rotated. If the patterning device MA and the substrate W are rotated in synchronization with one another (i.e., they are rotated to the same extent) a pattern applied to the substrate W will be applied in the same sense (i.e., it will have the same orientation) with respect to the substrate as it would if the patterning device MA and substrate W had not been rotated.

The patterning device MA and substrate W may be rotated about a common longitudinal axis 30 extending through the patterning device MA and substrate. However, in some circumstances, the apparatus may be arranged such that the radiation beam is reflected off or refracted by one or more elements after passing through or being reflected off the patterning device MA and before being incident on the substrate W. It may well be, therefore, that due to the path that the radiation beam takes between the patterning device MA and the substrate W, and the apparatus which it passes through or reflects off, the patterning device MA and substrate may need to be rotated in opposite directions, and even to different extents, in order to ensure that a pattern applied to the substrate W is applied in the same sense (i.e., in the same orientation with respect to the substrate) as would be the case if the patterning device MA and substrate W had not been rotated.

The patterning device MA may be rotated by moving a holder of the patterning device, or by moving the patterning device while held by the holder. Alternatively, the patterning device may be rotated by the taking the patterning device out of or off the holder, changing its orientation, and inserting it back into the holder. In another example, the patterning device MA itself may not be rotated, but the pattern provided by the patterning device MA may be rotated. For instance, if the patterning device MA comprises an array of individually controllable elements (e.g., mirrors) the pattern can be rotated by appropriate reconfiguration of the position and/or orientation of elements of the patterning device MA. The substrate W can be rotated by movement of an apparatus holding the substrate, or by moving the substrate while it is in or on the holder, or by removing the substrate from the holder, rotating it, and placing it back in the holder (using, for example, a robot handler of the like).

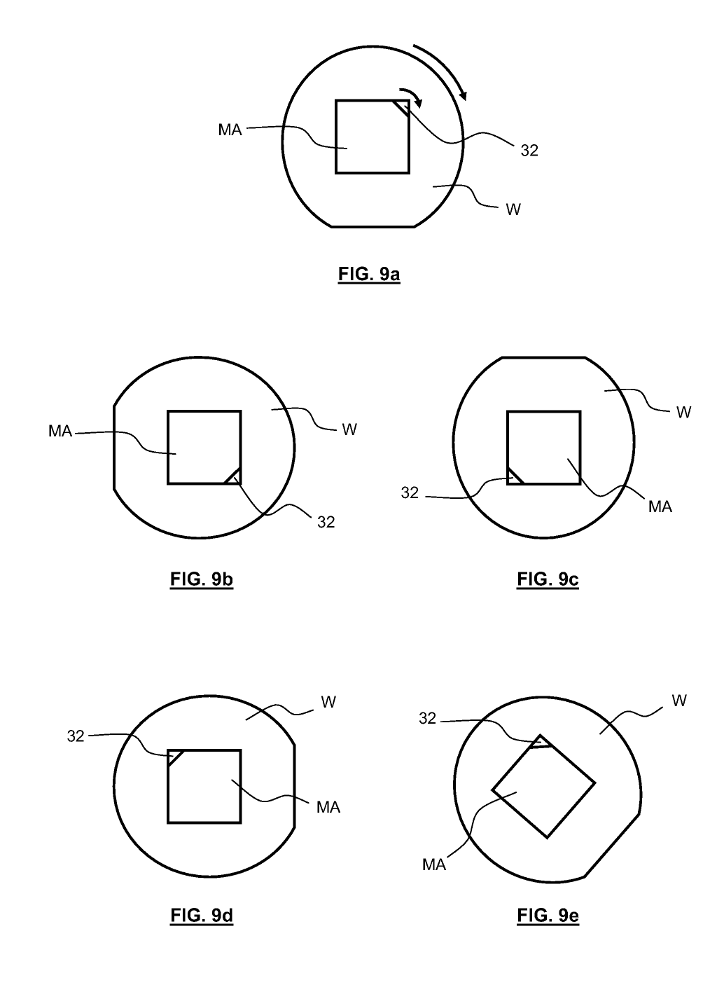

FIG. 9a shows the patterning device MA and substrate W of FIG. 8 in plan view. In the Figure, the relative orientation of the patterning device MA to the substrate W can be seen more easily with reference to a triangle 32 located in a corner of the patterning device MA. It will be appreciated that the triangle 32 is not actually a part of the patterning device MA, but is instead included in the Figures as an aid to explaining and depicting rotation of the patterning device MA. FIG. 9a shows how the patterning device MA and the substrate W can be rotated in the same direction. FIGS. 9b, 9c, and 9d show how the patterning device MA and the substrate W can be rotated 90°, 180°, or 270°. Rotating the patterning device MA and substrate W in 90° steps may be useful if the patterning device MA is square or rectangular (i.e., a shape with 90° corners). It may be straightforward to remove the patterning device MA from its holder and rotate it 90°, and re-insert it into the holder. Having said that, FIG. 9e shows that the patterning device MA and the substrate W may be rotated by any angle.

The appropriate degree of rotation of the fingerprint of the lithographic apparatus (or in other words, the degree of rotation of the patterning device and substrate) may be determined by trial and error, experimentation, previously obtained results (e.g., previously applied patterns to a substrate), modeling, simulation, or any other appropriate manner.

While the rotation of the fingerprint of the lithographic apparatus (or in other words relative rotation between a pattern of a patterning device and the fingerprint) has been described in relation to the application of patterns and mirrored patterns to different sides of a substrate, the invention may be useful in other applications. For instance, the fingerprint may be rotated in order to find a better fit or correlation between the distortion of applied patterns. For instance, different patterns may be distorted to different extents as a consequence of the fingerprint, and rotation of the fingerprint between the application of different patterns may better align the patterns and reduce overlay errors. The invention is also equally applicable to the application of patterns to the same side of a substrate.

It will be appreciated that the substrate and pattern (and/or patterning device) may be rotated in the same or opposite directions. The substrate and pattern (and/or patterning device) may be rotated by the same or different degrees of rotation. The substrate and pattern (and/or patterning device) may be rotated in-between the application of successive patterns to the substrate. The substrate and pattern (and/or patterning device) may be rotated in-between the application of overlaid patterns to the substrate. The substrate and pattern (and/or patterning device) may be rotated in-between the application of patterns to different sides of the substrate. The substrate and pattern (and/or patterning device) may be rotated in-between the application of a pattern and a mirror image of that pattern to the substrate. The substrate and pattern (and/or patterning device) may be rotated before or after flipping of the substrate has been undertaken. Flipping of the substrate is undertaken in order to provide patterns on another side of the substrate.

While specific embodiments of the invention have been described above, it will be appreciated that the invention may be practiced otherwise than as described. The description is not intended to limit the invention.

1. A lithographic apparatus comprising:
an illumination system for providing a beam of radiation;
a support structure for supporting a patterning device, the patterning device serving to impart the radiation beam with a pattern in its cross-section;
a substrate table for holding a substrate; and
a projection system for projecting the patterned radiation beam onto a target portion of the substrate;
wherein a pattern which the patterning device provides is rotatable; and
the substrate is rotatable, wherein, when in use, a rotation of the pattern is proportional to a rotation of the substrate, such that, after rotation, a pattern applied to the substrate is arranged to have a same orientation with respect to the substrate as it would if the pattern and substrate had not been rotated.

2. The lithographic apparatus of claim 1, wherein the substrate and pattern are rotatable in the same direction.

3. The lithographic apparatus of claim 1, wherein a degree of rotation of the substrate is the same as a degree of rotation of the pattern.

4. The lithographic apparatus of claim 1, wherein the substrate and pattern are rotatable by 90°, 180°, or 270°.

5. The lithographic apparatus of claim 1, wherein, in use, the projection system or illumination system imparts a fingerprint into the radiation beam which is characteristic of properties of the projection system or illumination system.

6. The lithographic apparatus of claim 5, wherein, in use, rotation of the substrate and pattern does not cause rotation of the fingerprint imparted into the radiation beam.

7. The lithographic apparatus of claim 1, wherein the pattern is arranged to be rotated by changing a configuration of one or more elements which constitute the patterning device.

8. The lithographic apparatus of claim 1, wherein the pattern is arranged to be rotated by rotating the patterning device.

9. The lithographic apparatus of claim 8, wherein the support structure is arranged to rotate the patterning device.

10. The lithographic apparatus of claim 8, wherein the pattern is arranged to be rotated by removing the patterning device from the support structure, rotating it, and then locating the patterning device back on the supporting device.

11. The lithographic apparatus of claim 1, wherein the substrate table is arranged to rotate the substrate.

12. A method comprising:
providing a substrate;
providing a beam of radiation using an illumination system;
using a patterning device to impart the radiation beam with a pattern in its cross-section; and
projecting the patterned radiation beam onto a target portion of the substrate;
wherein the method further comprises:
rotating the substrate; and
rotating a pattern provided by the patterning device,
rotation of the pattern being arranged to be proportional to rotation of the substrate, such that, after rotation, a pattern applied to the substrate is arranged to have the same orientation with respect to the substrate as it would if the pattern and substrate had not been rotated.

13. The method of claim 12, comprising rotating the substrate and pattern between the application of successive patterns to the substrate.

14. The method of claim 12, comprising rotating the substrate and pattern between the application of overlaid patterns to the substrate.

15. The method of claim 12, comprising rotating the substrate and pattern between the application of patterns to different sides of the substrate.

16. The method of claim 12, comprising rotating the substrate and pattern between the application of a pattern and a mirror image of that pattern to the substrate.

17. The method of claim 12, comprising rotating the substrate and pattern before or after flipping of the substrate has been undertaken.

18. The method of claim 17, wherein flipping of the substrate is undertaken in order to provide patterns on another side of the substrate.

19. A device manufactured according to the method of claim 12.
